(19) United States
(12) Patent Application Publication
(10) Pub. No.: US 2025/0140731 A1
(43) Pub. Date: May 1, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Sung-Hua CHUNG, Taichung City (TW); Liang-Pin CHEN, Taichung City (TW)

(21) Appl. No.: 18/754,549

(22) Filed: Jun. 26, 2024

(30) Foreign Application Priority Data
Oct. 31, 2023 (TW) 112141824

(51) Int. Cl. H01L 23/00; H01L 23/31; H01L 23/48; H01L 23/49; H01L 23/498; H01L 25/16

(52) U.S. Cl. CPC H01L 24/29; H01L 24/16; H01L 24/32; H01L 24/73; H01L 24/83; H01L 23/3107; H01L 23/481; H01L 23/49; H01L 23/49816; H01L 23/49822; H01L 24/24; H01L 25/162; H01L 2224/16227; H01L 2224/24146; H01L 2224/29082; H01L 2224/32225; H01L 2224/73204; H01L 2224/83986

(57) ABSTRACT

An electronic package and a manufacturing method thereof are provided, in which an electronic structure is tightly bonded to a carrier structure via a bonding layer, and the bonding layer includes a first bonding material and a second bonding material adjacent to the first bonding material, so that the second bonding material can fill in a deformation place of the first bonding material to ensure that no void is formed between the bonding layer and the carrier structure after the bonding layer is bonded to the carrier structure.

### CROSS-REFERENCE TO RELATED APPLICATIONS

The present application is based upon and claims the right of priority to TW patent application No. 112141824, filed Oct. 23, 2023, the disclosure of which is hereby incorporated by reference herein in its entirety for all purposes.

### BACKGROUND

### 1. Technical Field

The present disclosure relates to a semiconductor device, and more particularly, to an electronic package that can improve product yield and a manufacturing method thereof.

### 2. Description of Related Art

In order to ensure the continued miniaturization and multi-function of electronic products and communication equipment, semiconductor packaging needs to develop towards miniaturization in order to facilitate the connection of multiple contacts. Therefore, the industry has developed many advanced process packaging technologies. For example, in advanced process packaging, packaging types such as 2.5D packaging process, fan-out wiring with embedded bridge component process (FO-EB), etc. are commonly used.

FIG. 1A to FIG. 1D are schematic cross-sectional views showing a manufacturing method of a conventional semiconductor package 1.

As shown in FIG. 1A, a semiconductor bridging element 1a is provided, in which a silicon board body 11 has a plurality of conductive through-silicon vias (TSVs) 110, and a circuit portion 12 is formed on the silicon board body 11, wherein the circuit portion 12 includes at least one insulating layer 120 and conductive traces 121 formed on the insulating layer 120, and the conductive traces 121 are electrically connected to the conductive through-silicon vias 110, and a plurality of conductive bumps 122 are bonded on the outmost conductive traces 121, and the conductive bumps 122 are covered with a non-conductive film (NCF) 123. In addition, conductive bumps 111 are also disposed on exposed contacts of the conductive through-silicon vias 110, and the conductive bumps 111 are covered with a protective layer 112.

As shown in FIG. 1B, the semiconductor bridging element 1a is bonded to a wiring structure 14 on a carrier 9 via the non-conductive film 123 thereof, and the wiring structure 14 includes at least a dielectric layer 140 and a wiring layer 141 bonded to the dielectric layer 140, wherein the wiring structure 14 has a plurality of conductive pillars 13 thereon, so that the conductive pillars 13 are electrically connected to the wiring structure 14, and the conductive bumps 122 of the semiconductor bridging element 1a are electrically connected to the wiring layer 141 via solder bumps 142.

As shown in FIG. 1C, an encapsulant 15 is formed on the wiring structure 14 so that the encapsulant 15 covers the semiconductor bridging element 1a and the conductive pillars 13. Next, a circuit structure 10 is formed on the encapsulant 15 so that the circuit structure 10 is electrically connected to the plurality of conductive pillars 13 and the conductive bumps 111 of the semiconductor bridging element 1a, and then a plurality of semiconductor chips 16 are disposed on the circuit structure 10, so that the semiconductor bridging element 1a is electrically bridged the two semiconductor chips 16, and the semiconductor chips 16 are covered with another encapsulant 18.

As shown in FIG. 1D, the carrier 9 is removed to expose the wiring structure 14, and a singulation process is performed, and a plurality of solder balls 17 are formed on the wiring structure 14, so that the solder balls 17 are electrically connected to the wiring structure 14.

However, in the manufacturing method of the conventional semiconductor package 1, as shown in FIG. 1A, the non-conductive film 123 is easily deformed or the center thickness of the non-conductive film 123 is thinner during the manufacturing process, resulting in a void S formed between the non-conductive film 123 and the wiring structure 14 after the non-conductive film 123 is bonded to the wiring structure 14, so that the semiconductor bridging element 1a and the wiring structure 14 cannot be completely sealed. That is, the void S is located between the semiconductor bridging element 1a and the wiring structure 14, so moisture can easily infiltrate, and popcorn phenomenon is prone to occur in subsequent processes, resulting in reduced product yield.

Therefore, there is a need for a solution that addresses the aforementioned shortcomings in the prior art.

### SUMMARY

In view of the aforementioned shortcomings of the prior art, the present disclosure provides an electronic package, which comprises: a carrier structure; an electronic structure tightly bonded to the carrier structure via a bonding layer, wherein the bonding layer comprises a first bonding material and a second bonding material adjacent to the first bonding material to form a non-parallel double-layer structure; a plurality of conductive pillars disposed on and electrically connected to the carrier structure; an encapsulating layer formed on the carrier structure and covering the electronic structure and the plurality of conductive pillars; and a circuit structure disposed on the encapsulating layer and electrically connected to the electronic structure and the plurality of conductive pillars.

The present disclosure also provides a method of manufacturing an electronic package, the method comprises: bonding tightly an electronic structure to a carrier structure via a bonding layer, wherein the bonding layer comprises a first bonding material and a second bonding material adjacent to the first bonding material to form a non-parallel double-layer structure, and a plurality of conductive pillars are disposed on and electrically connected to the carrier structure; forming an encapsulating layer on the carrier structure to cover the electronic structure and the plurality of conductive pillars; and forming a circuit structure on the encapsulating layer, wherein the circuit structure is electrically connected to the electronic structure and the plurality of conductive pillars.

In the aforementioned method, the manufacturing process of the bonding layer comprises: forming the bonding layer on the electronic structure, and then disposing the electronic structure on the carrier structure via the bonding layer.

In the aforementioned method, the manufacturing process of the bonding layer comprises: forming the first bonding material on the electronic structure, disposing the electronic structure on the carrier structure via the first bonding material, and then filling the second bonding material in a gap between the first bonding material and the carrier structure to form the bonding layer.

In the aforementioned electronic package and method, the carrier structure comprises at least a dielectric layer and a wiring layer bonded to the dielectric layer, and the wiring layer is electrically connected to the electronic structure.

In the aforementioned electronic package and method, the electronic structure has a plurality of conductive bumps embedded in the bonding layer, and a plurality of openings corresponding to the plurality of conductive bumps are formed on the carrier structure after the encapsulating layer is formed on the carrier structure. Further, the present disclosure further comprises forming a wiring layer electrically connected to the plurality of conductive bumps in the plurality of openings.

In the aforementioned electronic package and method, the carrier structure is formed with a groove for accommodating the electronic structure.

In the aforementioned electronic package and method, the electronic structure is electrically connected to the circuit structure via a plurality of conductive bumps.

In the aforementioned electronic package and method, the first bonding material is a non-conductive film.

In the aforementioned electronic package and method, the second bonding material is a non-conductive paste.

In the aforementioned electronic package and method, the present disclosure further comprises disposing at least one electronic element on the circuit structure and electrically connecting the at least one electronic element to the circuit structure.

In the aforementioned electronic package and method, the present disclosure further comprises disposing a plurality of electronic elements on the circuit structure and electrically connecting the plurality of electronic elements to the circuit structure, wherein the electronic structure electrically bridges at least two of the plurality of electronic elements.

As can be understood from the above, in the electronic package and manufacturing method thereof of the present disclosure, the bonding layer comprises a first bonding material and a second bonding material adjacent to the first bonding material, so that the second bonding material can fill in the deformation place of the first bonding material to ensure that no void is formed between the bonding layer and the carrier structure after the bonding layer is bonded to the carrier structure. Therefore, compared with the prior art, the present disclosure can effectively and completely seal the electronic structure and the carrier structure to avoid the problem of moisture infiltration, so popcorn phenomenon will not easily occur in subsequent processes, thereby improving product yield.

### BRIEF DESCRIPTION OF THE DRAWINGS

FIG. 1A to FIG. 1D are schematic cross-sectional views showing a manufacturing method of a conventional semiconductor package.

FIG. 2A, FIG. 2B-1, FIG. 2C, FIG. 2D, FIG. 2E, FIG. 2F and FIG. 2G are schematic cross-sectional views illustrating a manufacturing method of an electronic package according to the first embodiment of the present disclosure.

FIG. 2B-2 is a schematic cross-sectional view illustrating another method of FIG. 2B-1.

FIG. 3A to FIG. 3D are schematic cross-sectional views illustrating a manufacturing method of an electronic package according to the second embodiment of the present disclosure.

FIG. 4A to FIG. 4E are schematic cross-sectional views illustrating a manufacturing method of an electronic package according to the third embodiment of the present disclosure.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

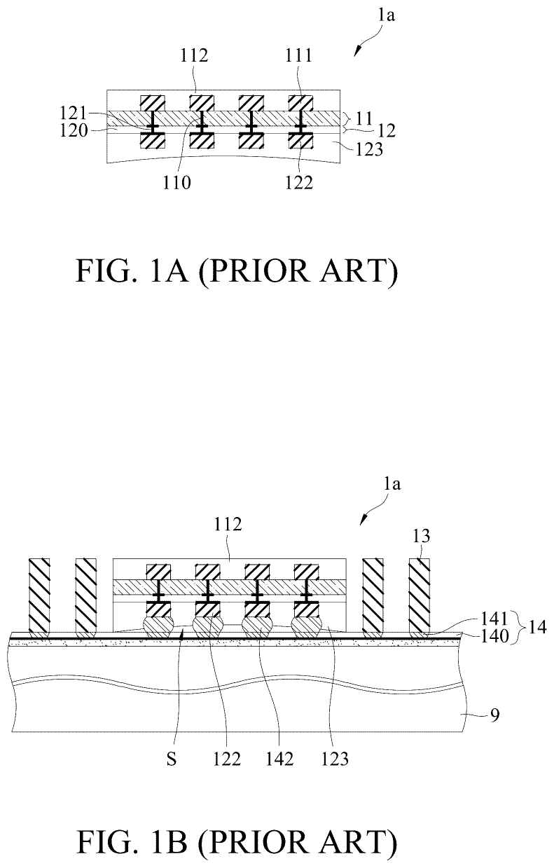

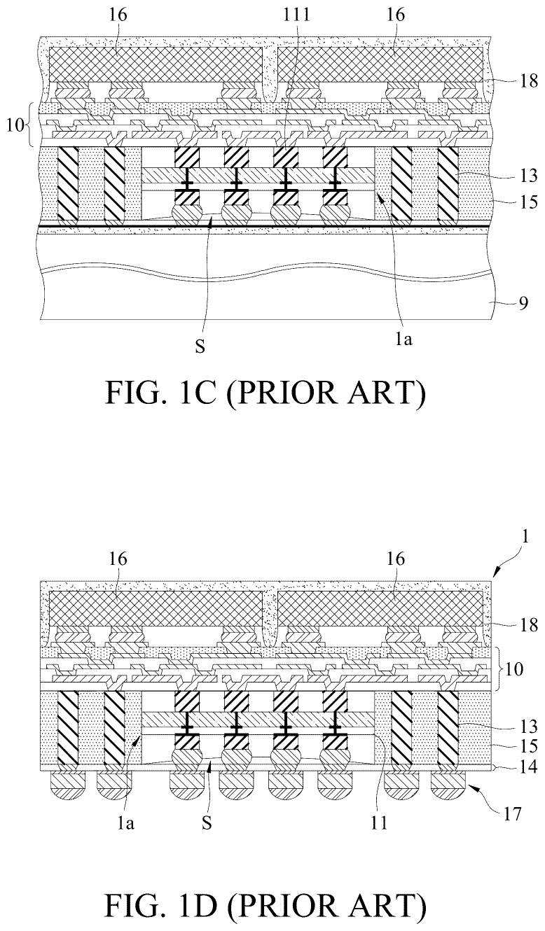

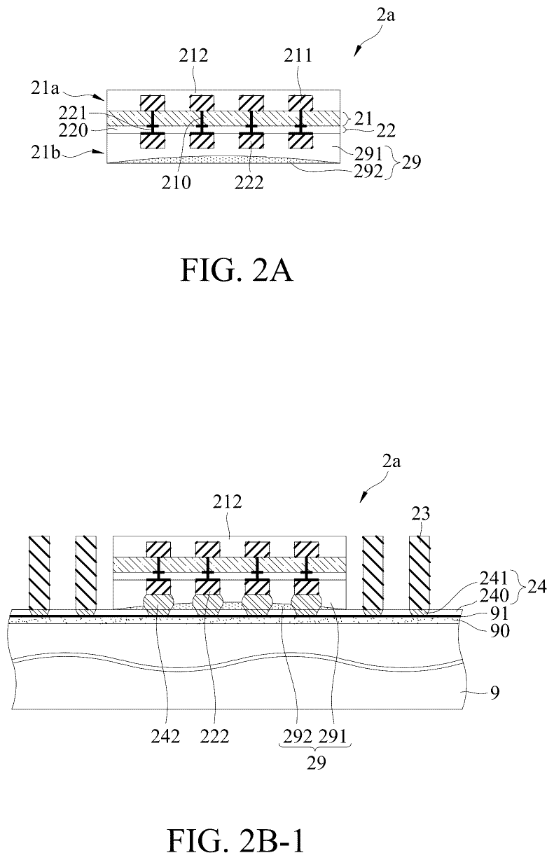

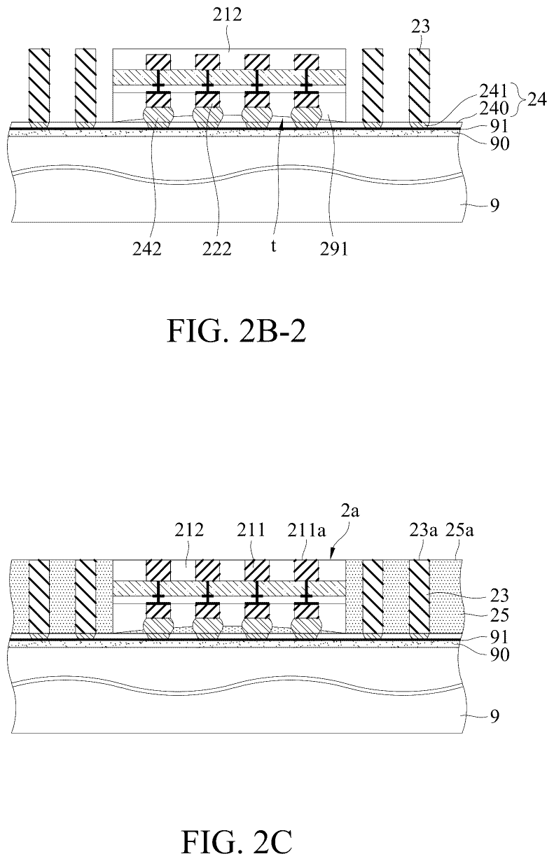

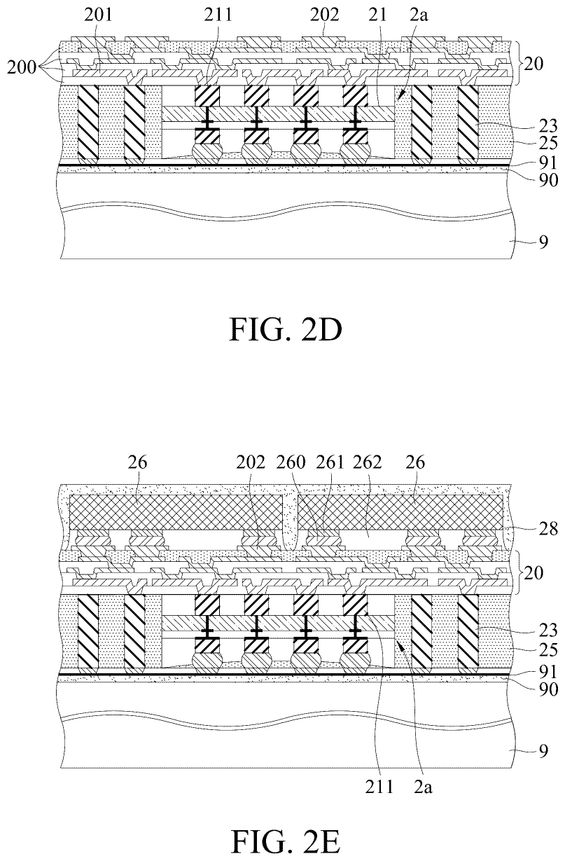

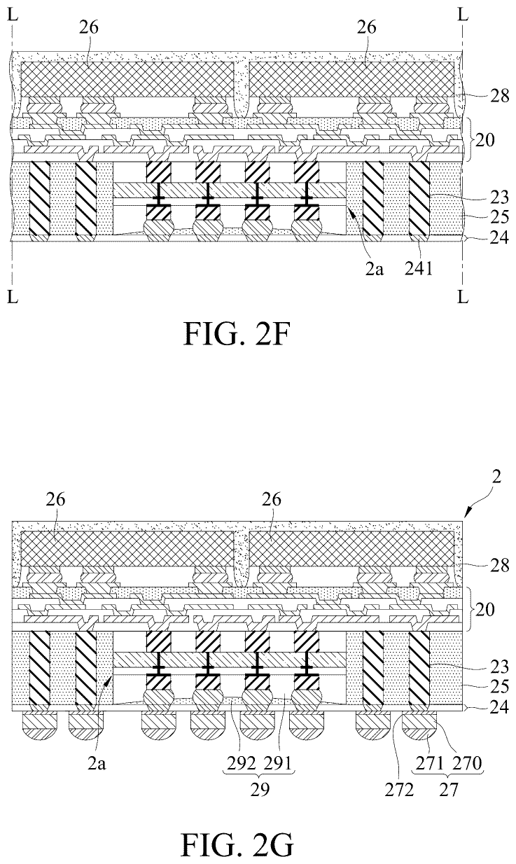

FIG. 2A, FIG. 2B-1, FIG. 2C, FIG. 2D, FIG. 2E, FIG. 2F and FIG. 2G are schematic cross-sectional views illustrating a manufacturing method of an electronic package 2 according to the first embodiment of the present disclosure.

As shown in FIG. 2A, an electronic structure 2a is provided and includes an electronic body 21 made of a semiconductor base material and a circuit portion 22 bonded to the electronic body 21, and the electronic body 21 is formed with a plurality of conductive vias 210 therein, wherein the electronic structure 2a has a first side 21a and a second side 21b opposing the first side 21a, and a plurality of conductive bumps 211, 222 electrically connected to the conductive vias 210 and/or the circuit portion 22 can be formed on the first side 21a and/or the second side 21b as required. It should be understood that the side of the electronic body 21 of the electronic structure 2a can be served as the first side 21a or the second side 21b as required, and the side of the circuit portion 22 can be served as the other side, but the present disclosure is not limited to as such.

In an embodiment, the conductive vias 210 are conductive through-silicon vias (TSVs), and the conductive bumps 211, 222 are metal bumps such as copper bumps, and the circuit portion 22 comprises at least one insulating layer 220 and conductive traces 221 bonded to the insulating layer 220, so that the conductive traces 221 are electrically connected to the conductive vias 210 and the conductive bumps 222.

Moreover, the conductive bumps 211 are covered by a protective layer 212 on the first side 21a, and the conductive bumps 222 are covered by a bonding layer 29 on the second side 21b, and the bonding layer 29 comprises a first bonding material 291 and a second bonding material 292 adjacent to the first bonding material 291. For example, the protective layer 212 is made of a dielectric material such as polybenzoxazole (PBO), polyimide (PI), prepreg (PP), or the like, and the first bonding material 291 is a non-conductive film (NCF), and the second bonding material 292 is a non-conductive paste (NCP).

Therefore, when a surface of the first bonding material 291 is an uneven surface, the second bonding material 292 can be used to fill the uneven surface of the first bonding material 291 to form a non-parallel double-layer structure, such that the outer surface of the bonding layer 29 forms a flat surface.

As shown in FIG. 2B-1, at least one electronic structure 2a and a plurality of conductive pillars 23 are disposed on a carrier 9.

The carrier 9 is, for example, a board body made of a semiconductor material (such as silicon or glass), on which a release layer 90 and a metal layer 91 made of such as titanium/copper are sequentially formed, for example, by coating, such that a carrier structure 24 is formed on the metal layer 91, wherein the electronic structure 2a is facing the carrier 9 with the bonding layer 29 thereof and tightly bonded onto the carrier structure 24, so that there is no gap between the bonding layer 29 and the carrier structure 24.

In an embodiment, the carrier structure 24 comprises at least a dielectric layer 240 and a wiring layer 241 bonded to the dielectric layer 240, and the dielectric layer 240 and the wiring layer 241 can be fabricated on the metal layer 91 of the carrier 9 by using a redistribution layer (RDL) process. For example, the dielectric layer 240 is made of a dielectric material such as polybenzoxazole (PBO), polyimide (PI), prepreg (PP), or the like.

Furthermore, the conductive bumps 222 of the electronic structure 2a are electrically connected to the wiring layer 241. For example, each of the conductive bumps 222 is connected onto the wiring layer 241 via a solder material 242, and the solder material 242 is embedded in the bonding layer 29.

Also, if the second bonding material 292 is not formed first when manufacturing the electronic structure 2a, as shown in FIG. 2B-2, then the second bonding material 292 can fill in a gap t between the first bonding material 291 and the carrier structure 24 after the electronic structure 2a is bonded onto the carrier structure 24 with the first bonding material 291 to form the bonding layer 29 (non-parallel double-layer structure), so that there is no gap between the bonding layer 29 and the carrier structure 24 (as shown in FIG. 2B-1).

The conductive pillars 23 are disposed on the carrier structure 24 and are electrically connected to the wiring layer 241.

In an embodiment, the conductive pillars 23 are made of a metal material such as copper or a solder material. For example, the conductive pillars 23 are electroplated on the wiring layer 241 via exposure and development.

As shown in FIG. 2C, an encapsulating layer 25 is formed on the carrier structure 24 so that the encapsulating layer 25 covers the electronic structure 2a and the conductive pillars 23, and a top surface of the protective layer 212, end surfaces 211a of the conductive bumps 211 and end surfaces 23a of the conductive pillars 23 are exposed from a surface 25a of the encapsulating layer 25.

In an embodiment, the encapsulating layer 25 is made of an insulating material, such as polyimide (PI), dry film, encapsulant such as epoxy resin, or molding compound. For example, the encapsulating layer 25 may be formed on the carrier structure 24 by liquid compound, injection, lamination, or compression molding.

In addition, a leveling process can be used to make the surface 25a of the encapsulating layer 25 flush with the top surface of the protective layer 212, the end surfaces 23a of the conductive pillars 23 and the end surfaces 211a of the conductive bumps 211, so that the end surfaces 23a of the conductive pillars 23 and the end surfaces 211a of the conductive bumps 211 are exposed from the surface 25a of the encapsulating layer 25. For example, the leveling process removes a portion of the material of the protective layer 212, a portion of the material of each of the conductive pillars 23, a portion of the material of each of the conductive bumps 211 and a portion of the material of the encapsulating layer 25 by grinding.

As shown in FIG. 2D, a circuit structure 20 is formed on the encapsulating layer 25 so that the circuit structure 20 is electrically connected to the plurality of conductive pillars 23 and the plurality of conductive bumps 211.

In an embodiment, the circuit structure 20 comprises at least an insulating layer 200 and a circuit layer 201 formed on the insulating layer 200 and is of such as a redistribution layer (RDL) specification, so that the circuit layer 201 is electrically connected to the plurality of conductive pillars 23 and the plurality of conductive bumps 211, wherein the outermost insulating layer 200 can be used as a solder-resist layer, and the outermost circuit layer 201 is exposed from the solder-resist layer to serve as electrical contact pads 202 such as micro pads (commonly known as μ-pads).

Moreover, the circuit layer 201 is made of copper, and the insulating layer 200 is made of a dielectric material such as polybenzoxazole (PBO), polyimide (PI), prepreg (PP), etc., or a solder-resist material such as solder mask (e.g., green solder mask), graphite (e.g., ink), etc.

As shown in FIG. 2E, a plurality of electronic elements 26 are disposed on the circuit structure 20, and then the electronic elements 26 are covered by a packaging layer 28.

Each of the electronic elements 26 is an active element, a passive element, or a combination of the active element and the passive element, wherein the active element is, for example, a semiconductor chip, and the passive element is, for example, a resistor, a capacitor, or an inductor.

In an embodiment, each of the electronic elements 26 is, for example, a semiconductor chip such as a graphics processing unit (GPU) or a high bandwidth memory (HBM). The electronic structure 2a is served as a bridging element (a bridge die) and is electrically connected to the circuit structure 20 via the conductive bumps 211, and thereby electrically bridges at least two of the electronic elements 26.

Furthermore, the electronic elements 26 can be electrically connected to the electrical contact pads 202 via a plurality of conductive bumps 261 and/or solder materials 260 in a flip-chip manner; alternatively, the electronic elements 26 can also be electrically connected to the electrical contact pads 202 via a plurality of bonding wires (not shown) in a wire-bonding manner; even the electronic elements 26 can electrically contact the electrical contact pads 202. However, the ways in which the electronic elements 26 are electrically connected to the circuit layer 201 are not limited to the above.

The packaging layer 28 is made of an insulating material, such as polyimide (PI), dry film, encapsulant such as epoxy resin, or molding compound, and the packaging layer 28 can be formed on the circuit structure 20 by lamination or molding. It should be understood that the material forming the packaging layer 28 may be the same as or different from the material of the encapsulating layer 25.

In an embodiment, an underfill 262 can be formed first between the electronic elements 26 and the circuit structure 20 to cover the conductive bumps 261 and the solder materials 260, and then the packaging layer 28 is formed to cover the underfill 262 and the electronic elements 26. Alternatively, in other embodiments, the packaging layer 28 can simultaneously cover the electronic elements 26 and the conductive bumps 261 without forming the underfill 262.

As shown in FIG. 2F, the carrier 9 and the release layer 90 thereon are removed, and then the metal layer 91 is removed to expose the carrier structure 24.

In an embodiment, when peeling off the release layer 90, the metal layer 91 is used as a barrier to avoid damaging the carrier structure 24. After removing the carrier 9 and the release layer 90 thereon, the metal layer 91 is removed by etching, such that the carrier structure 24 (even the wiring layer 241) is exposed.

As shown in FIG. 2G, a singulation process is performed along a cutting path L shown in FIG. 2F to obtain the electronic package 2, and a plurality of conductive elements 27 are formed on the carrier structure 24 so that the conductive elements 27 are electrically connected to the wiring layer 241, such that the electronic package 2 can be disposed on an electronic device (not shown) such as a packaging substrate or a circuit board via the conductive elements 27.

In an embodiment, each of the conductive elements 27 comprises a metal bump 270 made of such as copper and a solder material 271 formed on the metal bump 270. For example, an under-bump metallization (UBM) layer 272 may be formed on the wiring layer 241 to facilitate bonding with the metal bumps 270. It should be understood that when the number of contacts (inputs/outputs or IOs) is insufficient, build up operations can still be performed by the RDL process to reconfigure the number and position of the IOs of the carrier structure 24.

Therefore, in the manufacturing method of the electronic package 2 according to the first embodiment of the present disclosure, with the configuration of the second bonding material 292, the deformation place of the first bonding material 291 may be filled by the second bonding material 292 when the first bonding material 291 is deformed or the center thickness of the first bonding material 291 is thinner during the manufacturing process. Therefore, compared with the prior art, no void is formed between the bonding layer 29 and the carrier structure 24 after the bonding layer 29 is bonded to the carrier structure 24, so that the electronic structure 2a and the carrier structure 24 can be completely sealed to avoid the problem of moisture infiltration, such that popcorn phenomenon will not easily occur in subsequent processes, thereby improving product yield.

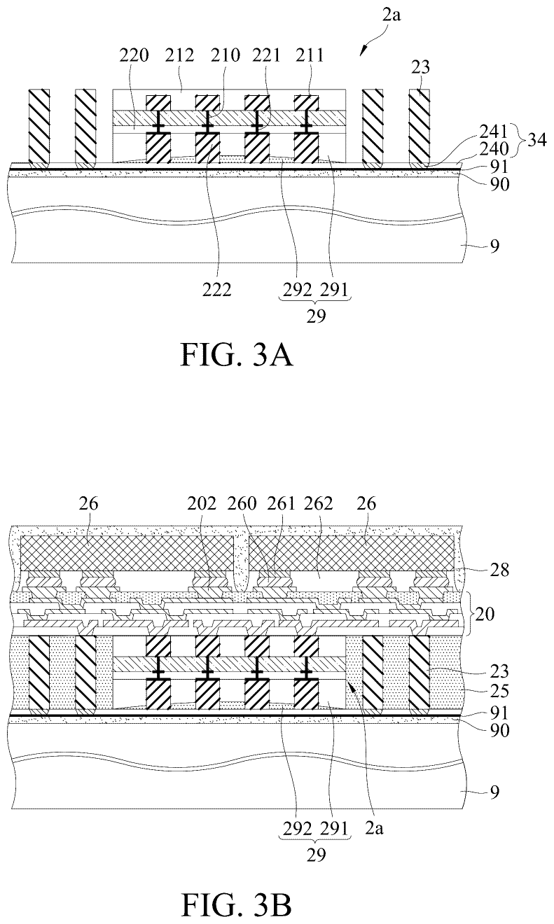

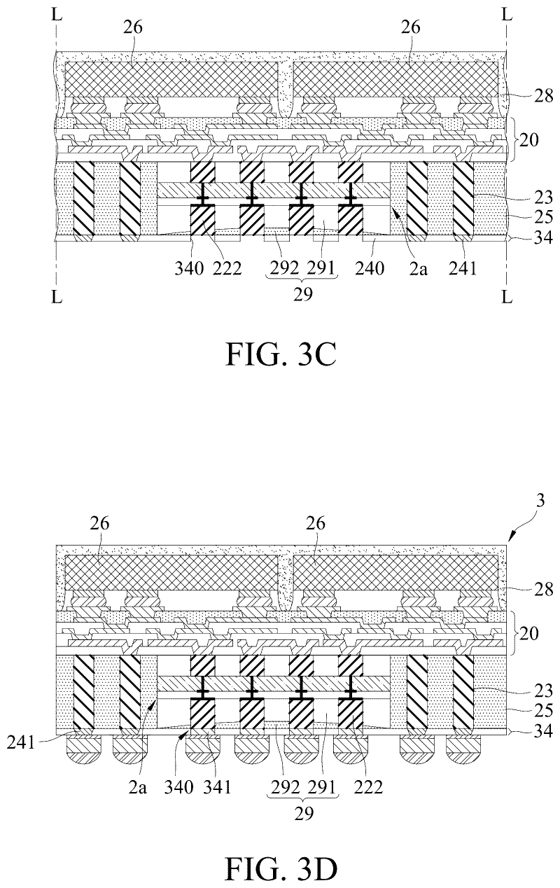

FIG. 3A to FIG. 3D are schematic cross-sectional views illustrating a manufacturing method of an electronic package 3 according to the second embodiment of the present disclosure. The difference between the second embodiment and the first embodiment lies in the way of the electronic structure 2a being disposed on a carrier structure 34. The other manufacturing processes are generally the same, so the similarities will not be described again. As shown in FIG. 3A, referring to a process similar to that disclosed in FIG. 2A, FIG. 2B-1 or FIG. 2B-2, the electronic structure 2a is bonded onto the dielectric layer 240 of the carrier structure 34 via the bonding layer 29, wherein the conductive bumps 222 are bonded onto the dielectric layer 240 and are not electrically connected to the wiring layer 241.

As shown in FIG. 3B, a process similar to that shown in FIG. 2C to FIG. 2E is performed to form the encapsulating layer 25, the circuit structure 20, the electronic elements 26 and the packaging layer 28.

As shown in FIG. 3C, the carrier 9 and the release layer 90 thereon are removed, and then the metal layer 91 is removed to expose the carrier structure 34. Then, a plurality of openings 340 are formed on the dielectric layer 240 of the carrier structure 34, so that the plurality of conductive bumps 222 are exposed from the plurality of openings 340.

In an embodiment, the openings 340 can be formed by laser or other methods, but the present disclosure is not limited to as such.

As shown in FIG. 3D, a wiring layer 341 electrically connected to the conductive bumps 222 is formed in the openings 340. Afterwards, a singulation process is performed along the cutting path L as shown in FIG. 3C, and a plurality of conductive elements 27 are formed on the carrier structure 34, so that the conductive elements 27 are electrically connected to the wiring layers 241, 341.

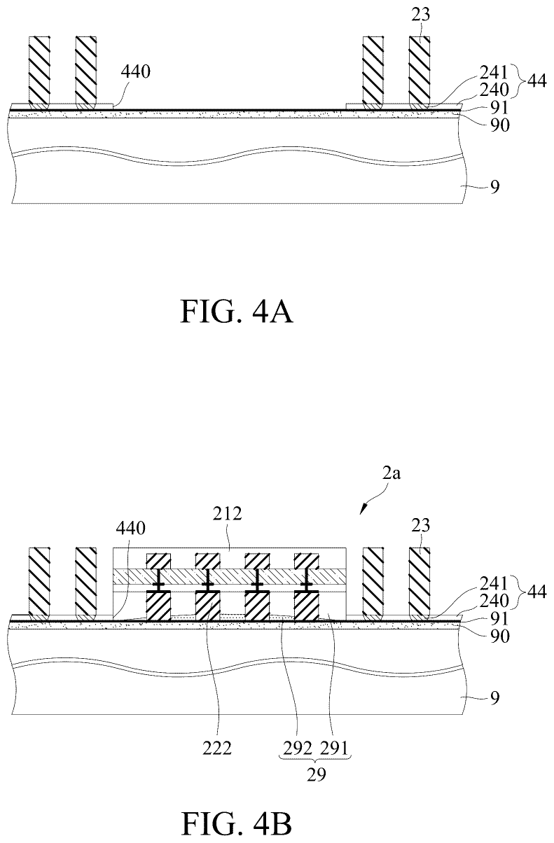

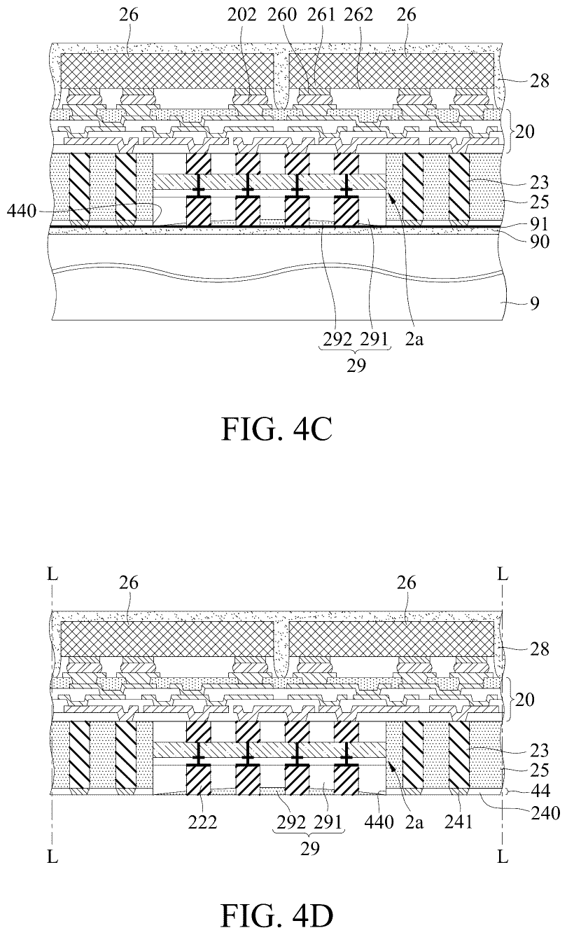

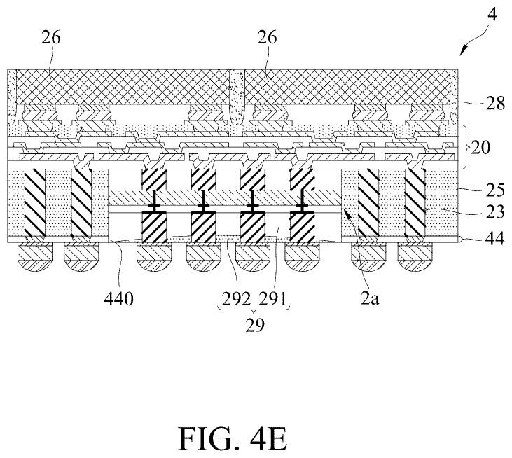

FIG. 4A to FIG. 4D are schematic cross-sectional views illustrating a manufacturing method of an electronic package 4 according to the third embodiment of the present disclosure. The difference between the third embodiment and the second embodiment lies in the way of the electronic structure 2a being disposed on a carrier structure 44. The other manufacturing processes are generally the same, so the similarities will not be described again.

As shown in FIG. 4A, referring to a process similar to that disclosed in FIG. 2A, FIG. 2B-1 or FIG. 2B-2, a groove 440 is formed on the dielectric layer 240 of the carrier structure 44, so that the metal layer 91 of the carrier 9 is exposed from the groove 440.

As shown in FIG. 4B, the electronic structure 2a is accommodated in the groove 440, so that the bonding layer 29 is bonded to the metal layer 91.

In an embodiment, the conductive bumps 222 may or may not contact the metal layer 91 as required.

As shown in FIG. 4C, a process similar to that shown in FIG. 2C to FIG. 2E is performed to form the encapsulating layer 25, the circuit structure 20, the electronic elements 26 and the packaging layer 28.

As shown in FIG. 4D, the carrier 9 and the release layer 90 thereon are removed, and then the metal layer 91 is removed to expose the carrier structure 44 and the electronic structure 2a.

In an embodiment, the conductive bumps 222 of the electronic structure 2a and the bonding layer 29 are exposed from the surface of the dielectric layer 240 of the carrier structure 44. For example, the outer surface of each of the conductive bumps 222 and the outer surface of the bonding layer 29 are flush with the outer surface of the dielectric layer 240 of the carrier structure 44 (or the bottom surface of the groove 440 of the carrier structure 44).

As shown in FIG. 4E, a singulation process is performed along the cutting path L shown in FIG. 4D, and a plurality of conductive elements 27 are formed on the electronic structure 2a and the carrier structure 34, so that the conductive elements 27 are electrically connected to the conductive bumps 222 of the electronic structure 2a and the wiring layer 241 of the carrier structure 44.

In addition, in an embodiment, a portion of the material of the packaging layer 28 can be removed by a leveling process, such as grinding, so that an upper surface of the packaging layer 28 is flush with an upper surface of each of the electronic elements 26, and the electronic elements 26 are exposed from the packaging layer 28.

The present disclosure provides an electronic package 2, 3, 4, which comprises: a carrier structure 24, 34, 44, an electronic structure 2a, a plurality of conductive pillars 23, an encapsulating layer 25 and a circuit structure 20.

The electronic structure 2a is tightly bonded to the carrier structure 24, 34, 44 via a bonding layer 29, wherein the bonding layer 29 comprises a first bonding material 291 and a second bonding material 292 adjacent to the first bonding material 291.

The conductive pillars 23 are disposed on and electrically connected to the carrier structure 24, 34, 44.

The encapsulating layer 25 is formed on the carrier structure 24, 34, 44 to cover the electronic structure 2a and the conductive pillars 23.

The circuit structure 20 is disposed on the encapsulating layer 25 and electrically connected to the electronic structure 2a and the conductive pillars 23.

In one embodiment, the carrier structure 24, 34, 44 comprises at least one dielectric layer 240 and wiring layers 241, 341 bonded to the dielectric layer 240, so that the wiring layers 241, 341 are electrically connected to the electronic structure 2a.

In one embodiment, the electronic structure 2a has a plurality of conductive bumps 222 embedded in the bonding layer 29, and a plurality of openings 340 corresponding to the conductive bumps 222 are formed on the carrier structure 34. For example, the wiring layer 341 electrically connected to the conductive bumps 222 is formed in the openings 340.

In one embodiment, the carrier structure 44 has a groove 440 for accommodating the electronic structure 2a.

In one embodiment, the electronic structure 2a is electrically connected to the circuit structure 20 via a plurality of conductive bumps 211.

In one embodiment, the first bonding material 291 is a non-conductive film.

In one embodiment, the second bonding material 292 is a non-conductive paste.

In one embodiment, at least one electronic element 26 is disposed on and electrically connected to the circuit structure 20.

In one embodiment, the electronic package 2, 3, 4 further comprises a plurality of electronic elements 26 disposed on the circuit structure 20 and electrically connected to the circuit structure 20, so that the electronic structure 2a electrically bridges at least two of the plurality of electronic elements 26.

In view of the above, in the electronic package and manufacturing method of the present disclosure, the second bonding material can fill in the deformation place of the first bonding material to ensure that no void is formed between the bonding layer and the carrier structure after the bonding layer is bonded to the carrier structure. Therefore, the electronic structure and the carrier structure can be completely sealed to avoid the problem of moisture infiltration, so popcorn phenomenon will not easily occur in subsequent processes, thereby improving product yield.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure;
an electronic structure tightly bonded to the carrier structure via a bonding layer, wherein the bonding layer comprises a first bonding material and a second bonding material adjacent to the first bonding material to form a non-parallel double-layer structure;
a plurality of conductive pillars disposed on and electrically connected to the carrier structure;
an encapsulating layer formed on the carrier structure and covering the electronic structure and the plurality of conductive pillars; and
a circuit structure disposed on the encapsulating layer and electrically connected to the electronic structure and the plurality of conductive pillars.

2. The electronic package of claim 1, wherein the carrier structure comprises a dielectric layer and a wiring layer bonded to the dielectric layer, and the wiring layer is electrically connected to the electronic structure.

3. The electronic package of claim 1, wherein the electronic structure has a plurality of conductive bumps embedded in the bonding layer, and a plurality of openings corresponding to the plurality of conductive bumps are formed on the carrier structure.

4. The electronic package of claim 3, further comprising a wiring layer formed in the plurality of openings and electrically connected to the plurality of conductive bumps.

5. The electronic package of claim 1, wherein the carrier structure has a groove for accommodating the electronic structure.

6. The electronic package of claim 1, wherein the electronic structure is electrically connected to the circuit structure via a plurality of conductive bumps.

7. The electronic package of claim 1, wherein the first bonding material is a non-conductive film.

8. The electronic package of claim 1, wherein the second bonding material is a non-conductive paste.

9. The electronic package of claim 1, further comprising at least one electronic element disposed on and electrically connected to the circuit structure.

10. The electronic package of claim 1, further comprising a plurality of electronic elements disposed on and electrically connected to the circuit structure, wherein the electronic structure electrically bridges at least two of the plurality of electronic elements.

11. A method of manufacturing an electronic package, comprising:
bonding tightly an electronic structure to a carrier structure via a bonding layer, wherein the bonding layer comprises a first bonding material and a second bonding material adjacent to the first bonding material to form a non-parallel double-layer structure, and a plurality of conductive pillars are disposed on and electrically connected to the carrier structure;
forming an encapsulating layer on the carrier structure to cover the electronic structure and the plurality of conductive pillars; and
forming a circuit structure on the encapsulating layer, wherein the circuit structure is electrically connected to the electronic structure and the plurality of conductive pillars.

12. The method of claim 11, wherein the carrier structure comprises a dielectric layer and a wiring layer bonded to the dielectric layer, and the wiring layer is electrically connected to the electronic structure.

13. The method of claim 11, wherein the electronic structure has a plurality of conductive bumps embedded in the bonding layer, and a plurality of openings corresponding to the plurality of conductive bumps are formed on the carrier structure after the encapsulating layer is formed on the carrier structure.

14. The method of claim 13, further comprising forming a wiring layer electrically connected to the plurality of conductive bumps in the plurality of openings.

15. The method of claim 11, wherein the carrier structure is formed with a groove for accommodating the electronic structure.

16. The method of claim 11, wherein the electronic structure is electrically connected to the circuit structure via a plurality of conductive bumps.

17. The method of claim 11, wherein the first bonding material is a non-conductive film.

18. The method of claim 11, wherein the second bonding material is a non-conductive paste.

19. The method of claim 11, wherein a manufacturing process of the bonding layer comprises: forming the bonding layer on the electronic structure, and then disposing the electronic structure on the carrier structure via the bonding layer.

20. The method of claim 11, wherein a manufacturing process of the bonding layer comprises: forming the first bonding material on the electronic structure, disposing the electronic structure on the carrier structure via the first bonding material, and then filling the second bonding material in a gap between the first bonding material and the carrier structure to form the bonding layer.

21. The method of claim 11, further comprising disposing at least one electronic element on the circuit structure and electrically connecting the at least one electronic element to the circuit structure.

22. The method of claim 11, further comprising disposing a plurality of electronic elements on the circuit structure and electrically connecting the plurality of electronic elements to the circuit structure, wherein the electronic structure electrically bridges at least two of the plurality of electronic elements.
